(19) United States
(12) Patent Application Publication
(10) Pub. No.: US 2008/0106292 A1
(43) Pub. Date: May 8, 2008

(54) Probe card having cantilever probes

(75) Inventors: Ka Ng Chui, Menlo Park, CA (US); Hyoseok Daniel Yang, Santa Clara, CA (US); Leonid Skorobogatov, Sunnyvale, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Corad Technology, Inc., Santa Clara, CA (US)

(21) Appl. No.: 11/592,565

(22) Filed: Nov. 2, 2006

(51) Int. Cl. G01R 31/02

(52) U.S. Cl. 324/758; 324/754

(57) ABSTRACT

A probe card includes a printed circuit board (PCB) and a probe ring coupled to the PCB. The probe card further includes a plurality of probes coupled to the PCB and to the probe card, and includes a plurality of tubes respectively associated with the plurality of probes. Each tube is configured to surround at least a portion of the probe that the tube is associated with. Each tube includes an inner dielectric portion and an outer conductive portion. The conductive portion of each tube is electrically coupled to the PCB.

### BACKGROUND OF THE INVENTION

The present invention relates to integrated circuit technology. More particularly, the present invention relate to a test method and a test apparatus for testing integrated circuits.

Integrated circuits (ICs) are typically tested prior to being used in an application, such as in a circuit board. IC testing is often performed on wafers prior to packaging, after the ICs are packaged, and are often tested once soldered onto a circuit board. Finished products that include ICs are also often tested prior to shipping to consumers, and these finished products tests often further test of the ICs of these products.

Testing an IC at the wafer level typically includes contacting a probe card to pads on the IC and driving electrical signals into and receiving electrical signal from the IC. More specifically, the probe card's probes are configured to contact to the bond pads of the IC to drive and receive the electrical signals. The electrical signals received from the IC are typically generated by the IC in response to the electrical signal driven into the IC by the probes. The electrical signals driven into the probe card and the IC are often generated by a signal generator, such as an automated test equipment (ATE) machine. The ATE machine may also be configured to receive the electrical signals from the IC via the probe card and compare the received electrical signal with a known good (i.e., passing) test pattern and/or a known bad (i.e., failing) test pattern to determine whether the IC will be packaged or rejected from packaging.

The clock rate at which an ATE machine can drive an IC is often limited by the crosstalk between test channels. Crosstalk includes sending a signal through one test channel and another test channel picking up the signal and transmitting the signal. Crosstalk may occur in an ATE machine, in the ATE machine's test fixtures (e.g., a load board), and/or in the probe card coupled to the text fixture.

New probe cards and new probe card methods are needed for testing ICs where crosstalk is reduced.

### BRIEF SUMMARY OF THE INVENTION

The present invention provides a test method and test apparatus for testing integrated circuit technology. More particularly, the present invention provides a probe card configured to reduce crosstalk between the probe card's probes.

According to one embodiment of the present invention, the probe card includes a printed circuit board (PCB) and a probe ring coupled to the PCB. The probe card further includes a plurality of probes coupled to the PCB and to the probe card, and includes a plurality of tubes respectively associated with the plurality of probes. Each tube is configured to surround at least a portion of the probe that is associated with the tube. Each tube includes an inner dielectric portion and an outer conductive portion. The conductive portion of each tube is electrically coupled to the PCB.

According to a specific embodiment, the conductive portion of each tube is coupled to a fixed voltage layer of the PCB. The fixed voltage layer may be grounded. The conductive portion of each tube may be soldered to the PCB, and may be soldered to a ground plane of the PCB.

According to another specific embodiment, the dielectric portion of each tube is polyimide, and the conductive portion of each tube is metal. The metal may be copper, copper with gold, nickel with gold, and/or silver. The metal may be plated to the dielectric portion. The tubes are configured to reduce crosstalk between the probes and to control the impedance of the probes.

According to another specific embodiment, a bent portion of each of the probes is annealed during or after bending, such that annealing the probes releases at least a portion of the molecular tension of the bent portion of the probes.

According to another embodiment, a method for assembling a probe card includes a) translating a probe in a first direction to position a probe tip of the probe at a focal plane of a microscope; b) translating a probe ring in a second direction and/or a third direction, which are substantially perpendicular to the first direction, to position the probe tip at a focal point of the microscope; c) coupling the probe to the probe ring; d) moving the probe ring by a known amount such that a probe tip of another probe positioned at the focal point corresponds to the position of a bond pad of an integrated circuit; e) moving the probe tip of the other probe to the focal point; f) coupling the other probe to the probe ring; and g) repeating steps d), e), and f) for a plurality of probes.

According to another embodiment, a method for assembling a probe card includes forming the ends of a plurality probes, wherein the ends of at least two of the probes have disparate contact areas; thereafter coupling the plurality of probes to a printed circuit board and a probe ring; and planarizing the ends of the probes. The step of forming may include grinding and/or polishing the ends. According to a specific embodiment, a first of the probes has an end with a first contact and a second of the probes has an end with a second contact area, and the first probe is configured for high current use. The high current use may include power supply use or ground use. The method may further include a) translating a probe in a first direction to position a probe tip of the probe at a focal plane of a microscope; b) translating a probe ring in a second direction and/or a third direction, which are substantially perpendicular to the first direction, to position the probe tip at a focal point of the microscope; c) coupling the probe to the probe ring; d) moving the probe ring by a known amount such that a probe tip of another probe positioned at the focal point corresponds to the position of a bond pad of an integrated circuit; e) moving the probe tip of the other probe to the focal point; f) coupling the other probe to the probe ring; and g) repeating steps d), e), and for a plurality of probes.

Another method for assembling a probe card includes contacting first and second electrodes proximate to a bend in a probe; passing current between the first and second electrodes via the probe to heat the probe, wherein the temperature of the probe at and near the bend is sufficient to relieve residual stress in the probe at and near the bend; cooling the probe; and coupling the probe to a printed circuit board (PCB) and a probe ring. The first and second electrodes may be disposed on different sides of the bend, and current is passed through the bend portion of the probe. The method may include repeating the contacting step, the current passing step, the cooling step, and the coupling step for a plurality of probes for which the first mentioned probe is a member. The method may further include a) translating a probe in a first direction to position a probe tip of the probe at a focal plane of a microscope; b) translating a probe ring in a second direction and/or a third direction, which are substantially perpendicular to the first direction, to position the probe tip at a focal point of the microscope; c) coupling the probe to the probe ring; d) moving the probe ring by a known amount such that a probe tip of another probe positioned at the focal point corresponds to the position of a bond pad of an integrated circuit; e) moving the probe tip of the other probe to the focal point; f) coupling the other probe to the probe ring; and g) repeating steps d), e), and f) for a plurality of probes.

According to a specific embodiment the method may further include forming an end of each of the plurality probes, wherein the ends of at least two of the probes have disparate contact areas; and planarizing the ends of the probes on the PCB and the probe ring. The method may further include forming a tube on each probe, wherein each tube is configured to surround at least a portion of the probe associated with the tube, each tube includes an inner dielectric portion and an outer conductive portion; and coupling the conductive portion of each tube to a portion of the PCB configured to carry a substantially constant voltage. The substantially constant voltage may be ground.

A better understanding of the nature and the advantages of the present invention may be gained with reference to the following detailed description and the accompanying drawings.

### BRIEF DESCRIPTION OF THE DRAWINGS

FIGS. 1A and 1B are simplified bottom and cross-sectional views of a probe card according to one embodiment of the present invention

FIG. 1C is a simplified cross-sectional view of a probe card according to an alternate embodiment of the present invention;

FIG. 2 is an end view of a tube according to one embodiment of the present invention;

FIGS. 3A and 3B are simplified bottom and cross-sectional views of a probe card 300 according to another embodiment of the present invention;

FIG. 3C is a simplified cross-sectional view of a probe card according to an alternate embodiment of the present invention;

FIG. 4 is a high-level flow chart for a method of aligning probes of a probe card according to one embodiment of the present invention;

FIG. 5 is a simplified perspective view of a set of probe according to another embodiment of the present invention; and

FIG. 6 is a simplified schematic of a probe tip according to one embodiment of the present invention.

### DETAILED DESCRIPTION OF THE INVENTION

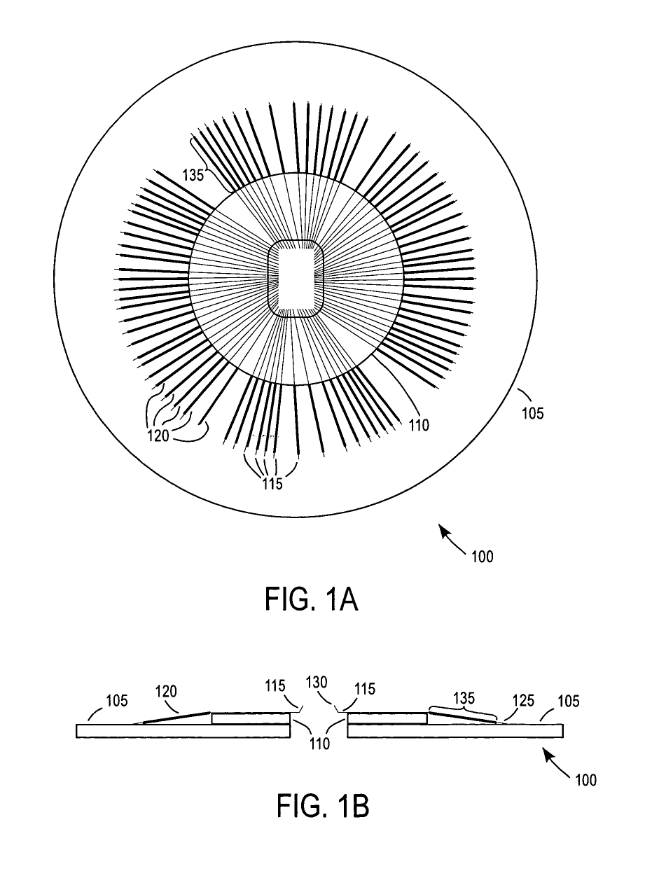

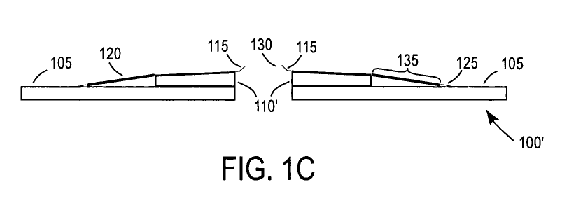

FIGS. 1A and 1B are simplified bottom and cross-sectional views of a probe card 100 according to one embodiment of the present invention. Probe card 100 includes a printed circuit board (PCB) 105, a probe ring 110, a plurality of probes 115, and a plurality of tubes 120. Probe card 100 is configured for use in testing integrated circuits. It should be understood that the probe cards and probes shown herein are not drawn to scale, but are drawn to emphasize certain inventive aspects of the described embodiments of the invention. The PCB of the probe card may be configured to be coupled to an automated test equipment (ATE) machine, and the probes of the probe card may be configured to contact the bond pads of an integrated circuit (IC). As referred to herein, a bond bad may include a pad on an IC that is configured to receive a bond wire, a solder ball, such as a flip chip ball, a solder covered ceramic or plastic ball, or the like. As further referred to herein, a bond pad may include a pad to which a solder ball or the like is coupled. Bond pads are sometimes referred herein as pads. The probe card may be configured to receive test signals from the ATE machine and transfer the test signals to the IC via the probes. The probe card may also be configured to receive signals from the IC and transfer the received signal to the ATE machine. The signals may be transferred through the probe card to test the IC. The ATE machine may be configured to determine whether the IC is operating properly based on the test signals sent to the IC and/or based on the signals received from the IC.

According to one embodiment, the probe card is configured such that each probe 115 is coupled to PCB 105 and to probe ring 110. A first end 125 of each probe may be coupled to an electrical contact on the PCB. The first ends of the probes may be soldered or otherwise electrically coupled to the PCB. A second end 130 of each probe is bent to contact a bond pad of an IC. Each probe may be coupled to the probe ring by epoxy or other known coupling device.

FIG. 1C is a simplified cross-sectional view of a probe card 100′ according to an alternate embodiment of the present invention. Probe card 100′ differs from probe card 100 in that probe card 100′ includes a probe ring 110′ that has a sloping top surface. The top surface slopes downward from the inside of the probe ring to the outside of the probe ring. The probes coupled to the probe ring may be contoured to follow the sloping top surface.

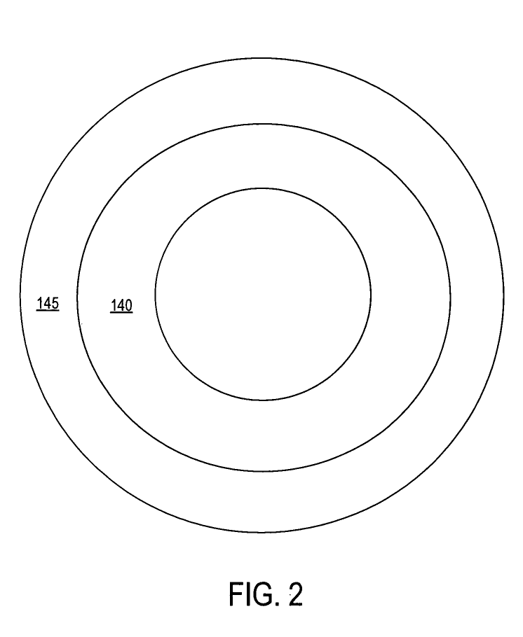

According to one embodiment, a portion 135 of each probe that is between the PCB and the probe ring is disposed in one of the tubes 120. FIG. 2 is an end view of one tube 120 according to one embodiment of the present invention. Each tube 120 may be configured similarly to the tube shown in FIG. 2. As shown in FIG. 2, the tubes include an inner dielectric layer 140 and an outer conductive layer 145. The dielectric layer may be polyimide or the like. The dielectric layer may be a tube or a coating. The conductive layer may also be a tube or a coating. For example, the dielectric layer may be a polyimide tube or the like, and the conductive layer may be a metal layer that is plated, painted or otherwise applied to the dielectric layer. Alternatively, the conductive layer may be a metal tube having an inner coating of dielectric material or having a dielectric tube inserted therein. The conductive layer may be copper, copper with gold, nickel with gold, silver or other metals.

Conductive layer 145 of each tube may be electrically coupled to the PCB. For example, the conductive layer of each tube may be soldered or otherwise coupled to the PCB. Each of the conductive layers of each tube may be coupled to a conductive portion of the PCB having a substantially constant voltage. The conductive portion of the PCB may be grounded or coupled to a voltage supply having constant voltage that is above or below ground. According to one embodiment, the impedance of the probes in the tubes is substantially similar to the impedance of traces in the PCB, traces of a test fixture of an ATE machine, and/or traces and circuits of the ATE machines. For example, the impedance of the probes in their respective tubes may be fifty Ohms or the like. Configuring the impedance of the probes substantially similar to other devices coupled to the probes provides relatively small signal reflection. Coupling the conductive layer to a ground layer (or the like) of the PCB provides relatively small crosstalk between the probes as the portion of the probes are substantially shielded from the signals in other probes.

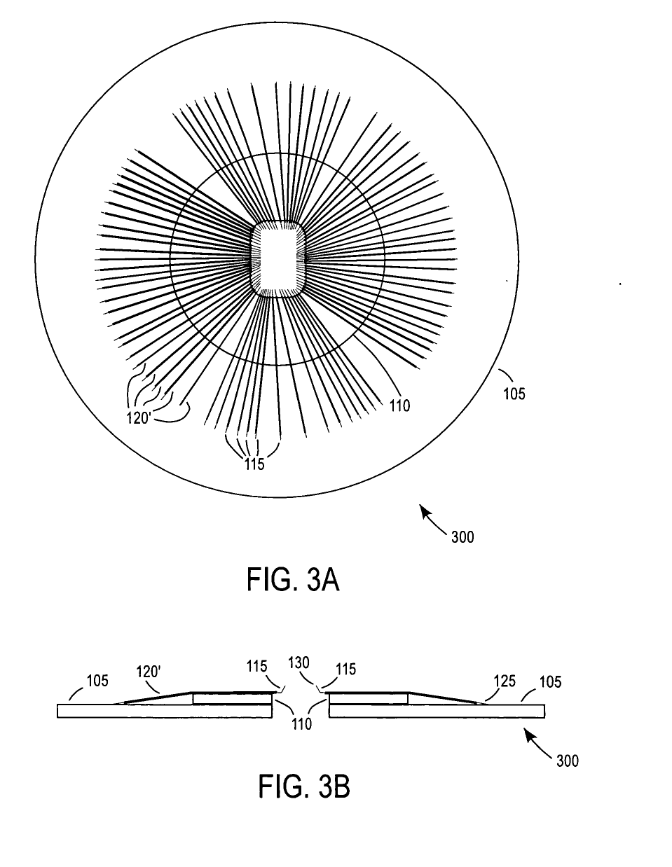

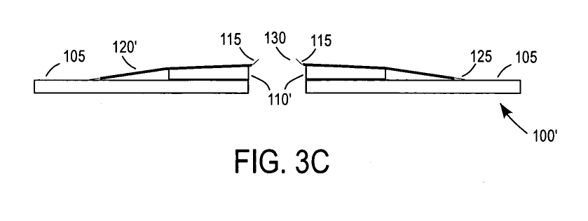

FIGS. 3A and 3B are simplified bottom and cross-sectional views of a probe card 300 according to another embodiment of the present invention. The same numeral scheme used above with respect to FIGS. 1A and 1B is used with respect to FIGS. 3A and 3B to identify the same or substantially similar elements of probe cards 100 and 300. Probe card 300 includes a printed circuit board (PCB) 105, a probe ring 110, and a plurality of probes 115, and a plurality of tubes 120′. Each tube 120′ may extend from substantially a first end 125 of its associated probe 115 to substantially a second end 130. At the first end of the probe the tube may be configured such that a sufficient portion of the probe is exposed so that the probe can be electrically coupled to the PCB. At the second end of the probe, the tube may be configured to end before the probe bends or after the probe bends. The tube may include an inner dielectric layer that is coated onto the probe by one of a variety of coating methods. The tube may also include an outer conductive layer that may be coated onto the dielectric layer by a one or more of a variety of coating methods, such as plating, painting or otherwise applied. The conductive layer may be copper, copper with gold, nickel with gold, silver or other metals. The conductive layer of each tube may be coupled to a substantially constant voltage layer (e.g., ground) as described above with respect to probe card 100.

FIG. 3C is a simplified cross-sectional view of a probe card 300′ according to an alternate embodiment of the present invention. Probe card 300′ differs from probe card 300 in that probe card 300′ includes a probe ring 110′ that has a sloping top surface. The top surface slopes downward from the inside of the probe ring to the outside of the probe ring. The probes coupled to the probe ring may be contoured to follow the sloping top surface.

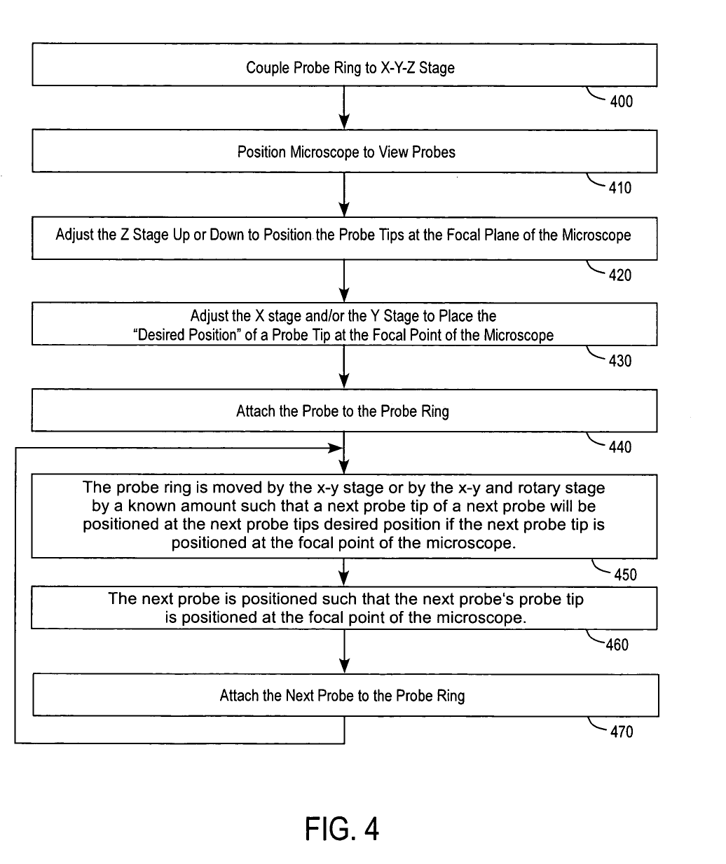

FIG. 4 is a high-level flow chart for a method of aligning probes of a probe card according to one embodiment of the present invention. The high-level flow chart is exemplary of the embodiment of the invention. Those of skill in the art will know of steps that may be added, deleted, combined, and/or substituted without deviating from the spirit and purview of the invention. These alternative embodiments are to be considered to be within the scope and purview of the invention. The claims are not limited by the high-level flow chart. The method of the flow chart may be used to align the probes of probe card 100, probe card 300 or other probe cards. At a step 400, a probe ring, such as probe ring 110, having a plurality of probes coupled thereto is coupled to an stage that is configured to move the probe ring and probes in the x, y, and or z directions (e.g., orthogonal directions). At a step 410, a microscope is positioned to view the probes. At a step 420, the probe ring and probes are moved along the z axis by the stage such that the tips of the probes are positioned at the focal plane of the microscope. The z stage may be substantially fixed subsequent to moving the probe tips into the focal plane. At a step 430, for a given probe, the x and y stages are adjusted so that the “desired position” of the probe tip is at the focal point of the microscope. The desired position of the probe tip corresponds to the position of a bond pad of an IC that the probe tip is configured to contact. At a step 440, the probe is fixed to the probe ring by epoxy or the like. At a step 450, the probe ring is moved by the x-y stage or by an x, y and rotary stage by a known amount such that a next probe tip of a next probe will be positioned at the next probe tips desired position if the next probe tip is positioned at the focal point of the microscope. At step 460, the next probe is positioned such that the next probe's probe tip is positioned at the focal point of the microscope. At a step 470, the next probe is fixed to the probe ring by epoxy or the like. Steps 450, 460, and 470 may be repeated for each subsequent probe to be coupled to the probe ring.

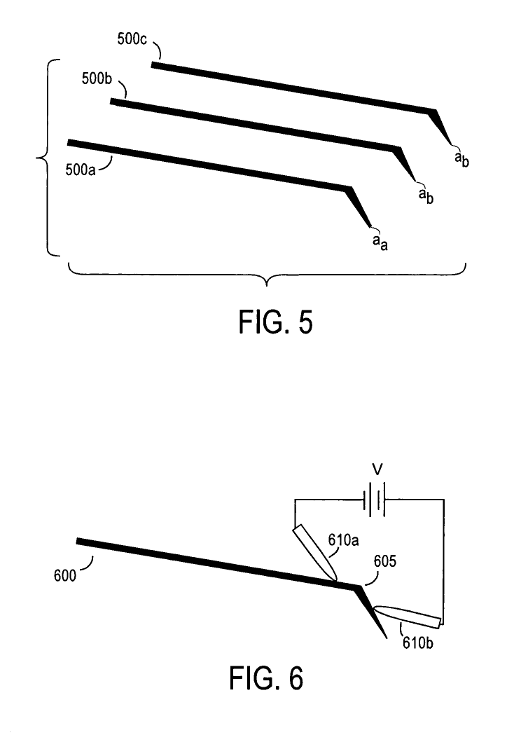

FIG. 5 is simplified perspective view of a set of probe tips 500 according to another embodiment of the present invention. The probe tips are labeled with the base reference numeral 500 and an alphabetic suffix. Probe tips 500 might be the tips of probes 115 of probe card 100, probe card 300 or the like. The probe tips have a variety of end dimensions. For example, the end of probe tip 500a has a contact area “aₐ” that is larger than the “a_{b}” of the end of probe tip 500b, and the contact area “a_{c}” of the end of probe tip 500c. While the contact areas of the ends of the probe tips 500b and 500c are shown as being substantially equal, the ends of these probe tips may have different contact areas. The ends of the probe tips may be substantially round, oblong, capricious or other shape. According to one embodiment, probes with ends that have relatively larger contact areas than other ends may be configured used for relatively high current use. For example, a probe with an end having a relatively large contact area aₐ, may be used for a power supply (e.g., VCC), a ground, or the like. Probes having ends with relatively smaller contact areas, such as a_{b} or a_{c}, may by used for IC pads that draw relatively less current than a power pad, a ground pad or the like.

According to one embodiment, the ends of the probe tips 500 are ground, polished, etc. prior to being coupled to a PCB and probe ring. The ends of the probe tips may be ground, polished, etc. until the desired contact areas aₐ, a_{b}, a_{c}, etc. of the ends of the probe tips are achieved. Subsequent to grinding, the probes associated with probe tips 500 may be coupled to a PCB and a probe ring. For example, the probes may be coupled to a PCB and a probe ring according to the probe coupling method described above and outlined in the high-level flow chart of FIG. 4. According to the method of FIG. 4, as the probe tip of each probe is moved into substantially the same plane (i.e., the focal plane of the microscope) the ends of probe tips are planarized by the described method. As such the ends of the probe tips might not be ground to planarize the probe tips. Accordingly, the contact areas of the ends of the probe tips set in the grinding step might not be changed after the probes are coupled to a PCB and a probe ring as the end of the probes are planarized without a grinding step. As such the contact areas of the ends of the probe tips may be relatively precisely controlled.

FIG. 6 is a simplified schematic of a probe 600 according to one embodiment of the present invention. Probe 600 may be a probe of probe card 100, probe card 300 or the like. According to one embodiment of the present invention, subsequent to bending the probe tip (e.g., at room temperature) of the probe, the probe tip is annealed at a bend 605 and proximate to the bend. According to one embodiment, a first electrode 610a is placed in contact with the probe on a first side of the bend, and a second electrode 610b is placed in contact with the probe on a second side of the bend. Current may be passed between the electrodes via the probe to heat the probe at and proximate to the bend. In the heating step, the temperature of the probe may be sufficient to remove at least a portion of the internal stress (i.e., molecular tension) in the probe at and near the bend where the stress is introduced into the probe by bending the probe. A temperature at which molecular tension in a probe is substantially released due to heating is sometimes referred to herein as the “transition temperature.” If a probe is tungsten, for example, the bend and portions of the probe near the bend may be heated to approximately 400° C. or higher. Subsequent to heating the probe, the probe is allowed to cool. The probe may be in an argon gas environment (or other inert gas environment) during the heating and cooling steps to limit and/or prevent oxidation of the probe. According to one embodiment, the portion of the probe on either side of the bend may be held substantially fixed during the heating and/or cooling steps to provide that the angle of the bend remains substantially unchanged by the heating and/or cooling steps. According to another embodiment, the probe may be bent while the probe is raised substantially to or above the transition temperature (e.g., approximately 400° C. or higher for tungsten probes). Annealing a probe at a bend tends to remove internal stress to inhibit the bend from opening.

It is to be understood that the exemplary embodiments described above are for illustrative purposes only and that various modifications or changes in light thereof will be suggested to persons skilled in the art and are to be included within the spirit and purview of this application and scope of the appended claims. For example, while the probe card shown in FIG. 1A is configured to test a single IC on a wafer, the probe card may be configured to test a plurality of ICs on a wafer. Therefore, the above description should not be understood as limiting the scope of the invention as defined by the claims.

What is claimed is:

1. A probe card comprises:
a printed circuit board (PCB);
a probe ring coupled to the PCB;
a plurality of probes coupled to the PCB and to the probe card; and
a plurality of tubes respectively associated with the plurality of probes, wherein:
each tube is configured to surround at least a portion of the probe that is associated with the tube,
each tube includes an inner dielectric portion and an outer conductive portion, and
the conductive portion of each tube is electrically coupled to the PCB.

2. The probe card of claim 1, wherein each tube is a prefabricated tube into which an associated probe is positioned, or each tube is formed by coating the dielectric portion onto an associated probe.

3. The probe card of claim 1, wherein the conductive portion of each tube is coupled to a ground of the PCB.

4. The probe card of claim 1, wherein the conductive portion of each tube is coupled to a fixed voltage layer of the PCB.

5. The probe card of claim 1, wherein the conductive portion of each tube is soldered to the PCB.

6. The probe card of claim 5, wherein the conductive portion of each tube is soldered to a ground plane of the PCB.

7. The probe card of claim 1, wherein the inner dielectric portion of each tube is a dielectric material.

8. The probe card of claim 1, wherein the dielectric material is polyimide.

9. The probe card of claim 1, wherein the conductive portion of each tube is metal.

10. The probe card of claim 1, wherein the metal is copper, copper with gold, nickel with gold, and/or silver.

11. The probe card of claim 10, wherein the metal is plated to the dielectric portion.

12. The probe card of claim 1, wherein the tubes are configured to reduce crosstalk between the probes.

13. The probe card of claim 1, wherein the tubes are configured to control the impedance of the probes.

14. The probe card of claim 1, wherein a bent portion of each of the probes is annealed during or after bending.

15. The probe card of claim 14, wherein annealing releases molecular tension of the bent portion of the probes.

16. A probe card comprises:
a plurality of probes;
a plurality of tubes respectively associated with the plurality of probes, wherein:
each tube is configured to surround at least a portion of the probe that is associated with the tube,
each tube includes an inner dielectric portion and an outer conductive portion, and
the conductive portion of each tube is coupled to a common voltage.

17. The probe card of claim 16, wherein each tube is a prefabricated tube into which an associated probe is positioned, or each tube is formed by coating the dielectric portion onto an associated probe.

18. The probe card of claim 16, wherein the common voltage is ground.

19. The probe card of claim 18, wherein the tubes are configured to reduce crosstalk between the probes.

20. A method of positioning the probe tips of a plurality of probes of a probe card comprises:
a) translating a probe in a first direction to position a probe tip of the probe at a focal plane of a microscope;
b) translating a probe ring in a second direction and/or a third direction, which are substantially perpendicular to the first direction, to position the probe tip at a focal point of the microscope;
c) coupling the probe to the probe ring;
d) moving the probe ring by a known amount such that a probe tip of another probe positioned at the focal point corresponds to the position of a bond pad of an integrated circuit;
e) moving the probe tip of the other probe to the focal point;
f) coupling the other probe to the probe ring; and
g) repeating steps d), e), and f) for a plurality of probes.

21. A method for assembling a probe card comprising:
forming the ends of a plurality probes, wherein the ends of at least two of the probes have disparate contact areas; thereafter
coupling the plurality of probes to a printed circuit board and a probe ring; and
planarizing the ends of the probes.

22. The method claim 21, wherein the step of forming includes grinding and/or polishing the ends.

23. The method claim 21, wherein a first of the probes has an end with a first contact area and a second of the probes has an end with a second contact, and the first probe is configured for high current use.

24. The method of claim 23, wherein the high current use includes power supply use or ground use.

25. The method claim 21, wherein the planarizing step includes:
a) translating a probe in a first direction to position a probe tip of the probe at a focal plane of a microscope;
b) translating a probe ring in a second direction and/or a third direction, which are substantially perpendicular to the first direction, to position the probe tip at a focal point of the microscope;
c) coupling the probe to the probe ring;
d) moving the probe ring by a known amount such that a probe tip of another probe positioned at the focal point corresponds to the position of a bond pad of an integrated circuit;
e) moving the probe tip of the other probe to the focal point;
f) coupling the other probe to the probe ring; and
g) repeating steps d), e), and f) for a plurality of probes.

26. A method for assembling a probe card comprising:
contacting first and second electrodes proximate to a bend in a probe;
passing current between the first and second electrodes via the probe to heat the probe, wherein the temperature of the probe at and near the bend is sufficient to relieve at least a portion of a residual stress in the probe at and near the bend;
cooling the probe; and
coupling the probe to a printed circuit board (PCB) and a probe ring.

27. The method of claim 26, wherein the first and second electrodes are disposed on different sides of the bend portion of the probe, and current is passed through the bend portion of the probe.

28. The method of claim 26, further comprising repeating the contacting step, the current passing step, the cooling step, and the coupling step for a plurality of probes for which the first mentioned probe is a member.

29. The method of claim 28, further comprising:
prior to the coupling step, forming an end of each of the plurality probes, wherein the ends of at least two of the probes have disparate contact areas; and
planarizing the ends of the probes on the PCB and the probe ring.

30. The method of claim 29, wherein the planarizing step includes:
a) translating a probe in a first direction to position a probe tip of the probe at a focal plane of a microscope;
b) translating a probe ring in a second direction and/or a third direction, which are substantially perpendicular to the first direction, to position the probe tip at a focal point of the microscope;
c) coupling the probe to the probe ring;
d) moving the probe ring by a known amount such that a probe tip of another probe positioned at the focal point corresponds to the position of a bond pad of an integrated circuit;
e) moving the probe tip of the other probe to the focal point;
f) coupling the other probe to the probe ring; and
g) repeating steps d), e), and f) for a plurality of probes.

31. The method of claim 28, further comprising:
forming a tube on each probe, wherein each tube is configured to surround at least a portion of the probe associated with the tube, each tube includes an inner dielectric portion and an outer conductive portion; and
coupling the conductive portion of each tube to a portion of the PCB configured to carry a substantially constant voltage.

32. The method of claim 31, wherein the substantially constant voltage is ground.
